(19) United States
(12) Patent Application Publication
(10) Pub. No.: US 2011/0005454 A1
(43) Pub. Date: Jan. 13, 2011

(54) Plasma Reactor, and Method for the Production of Monocrystalline Diamond Layers

(76) Inventors: Matthias Schreck, Augsburg (DE); Stefan Gsell, Dillingen (DE); Martin Fischer, Augsburg (DE)

Correspondence Address: FAY KAPLUN & MARCIN, LLP, 150 BROADWAY, SUITE 702, NEW YORK, NY, 10038, US

(21) Appl. No.: 12/664,935

(22) PCT Filed: Jun. 16, 2008
(86) PCT No.: PCT/EP2008/004840

§ 371 Date: Apr. 28, 2010

(30) Foreign Application Priority Data
Jun. 20, 2007 (DE) 10 2007 028 293.3

(51) Int. Cl. C30B 25/02; H05H 1/46

(52) U.S. Cl. 117/103; 118/723 MW

(57) ABSTRACT

A plasma reactor and a method for production on wafers over a large area of monocrystalline diamond layers. The plasma reactor includes at least two flat electrodes having surfaces orientated towards each other, the electrodes being delimited respectively by an edge; a plasma region producing a plasma between the surfaces of the electrodes with an ion saturation current density of equal to or greater than 0.001 A/cm2, wherein a gas is introduced into the plasma region; and a device supplying microwaves having at least one frequency, the microwaves radiating into the plasma region and introducing a power into the plasma region contributing to the plasma production. The ion saturation current density of equal to or greater than 0.001 A/cm2 is maintained by controlling at least one of (a) a spacing between the electrodes, (b) the power of the microwaves, and (c) the frequency of the microwaves.

The invention relates to a plasma reactor with which monocrystalline diamond layers can be produced on wafers over a large area. The invention relates in addition to a method for the production of such diamond layers.

For the production of large-area diamond layers, heteroepitaxy, i.e. the deposition on monocrystalline foreign substrates, represents the most promising concept. Firstly, diamond nuclei are deposited hereby in an epitaxial nucleation (epitaxial formation of nuclei) and subsequently the diamond layer is grown. In order in fact to be able to produce monocrystalline diamond layers, control of the epitaxial nucleation is crucial.

Nucleation methods for depositing diamond on silicon or silicon carbide have been known for some time. The nucleation can be controlled here relatively easily because the nuclei can grow immediately under the nucleation conditions.

The nucleation method becomes significantly more difficult if the diamond layer is intended to be deposited on iridium. This metal, as only material at present, has the potential for deposition of large-area monocrystalline diamond layers. On iridium, the nuclei are produced embedded in a 1 nm thick carbon layer. Because of the intensive ion bombardment, they cannot grow upwards during the nucleation step.

Basically, the nucleation takes place in that the substrate to be coated is subjected to an activated gas phase which contains carbon and is thereby at a negative potential so that bombardment with positive ions takes place. For the epitaxial nucleation on iridium, various arrangements have been proposed for this purpose.

Of particular interest are those methods in which microwaves together with a direct voltage are used to produce an electrical field. For example, a very small substrate of approx. 1 cm edge length can be grown below a very large plasma ball of a diameter of 10 cm. The sample hereby forms the cathode whilst the anode is configured as an annular electrode which surrounds the sample in a plane parallel to the surface of the sample. As a result, the current flow is concentrated on the sample. The plasma ball is produced within the annular electrode above the sample and is permeated by the electrical field lines of the applied direct voltage. The method is however restricted to the mentioned small substrates of approx. 1 cm edge length. In the case of larger substrate surfaces, no nucleation could be produced even by increasing the externally-applied voltage.

In Fujisaki et al., Diamond Relat. Mater. 11 (2002) 478, it is proposed to use pointed electrodes which lead to a current concentration on the substrate. Once again, the sample to be coated is the cathode whilst the pointed electrodes form the anode. Microwaves are also radiated here into the region of the plasma. However with this method the nucleatable surface is also very small. In order to enlarge the surface, the authors propose a multi-antenna arrangement and also a displaceable substrate holder.

Sawabe et al., Diamond Relat. Mater. 13 (2004) 1975, propose in addition purely direct voltage discharge without microwave irradiation. A main disadvantage of purely DC discharges is the instability at high pressures. The discharge here shows filamentation and changes easily into an arc discharge (Y. P. Raizer: Gas Discharge Physics, Springer, Berlin 1991).

It is therefore the object of the present invention to indicate a device and also a method with which diamond nucleation and -coating is possible not only on silicon but also on iridium over a large area. This object is achieved by the plasma reactor according to claim 1 and the method for nucleation of diamond on a wafer according to claim 44. Claims 53 and 54 indicate uses of the plasma reactor according to the invention. Advantageous developments of the plasma reactor according to the invention and of the method according to the invention are given in the respective dependent claims.

It emerges from tests that the ion saturation current density plays a crucial role as a measure of the activation of the plasma above the cathode for the nucleation of diamond on iridium layers. The ion saturation current density is the ion saturation current divided by the area of the cathode. The ion saturation current is hereby defined by the following measurement.

Firstly, a gas is brought between two plate-shaped parallel electrodes and then microwaves are radiated into the gas between the plates. The penetration depth of the microwaves as a function of the frequency and of the electron density is described for example in A. L. Vikharev et al., Diamond Relat. Mater. 15 (2006) 502.

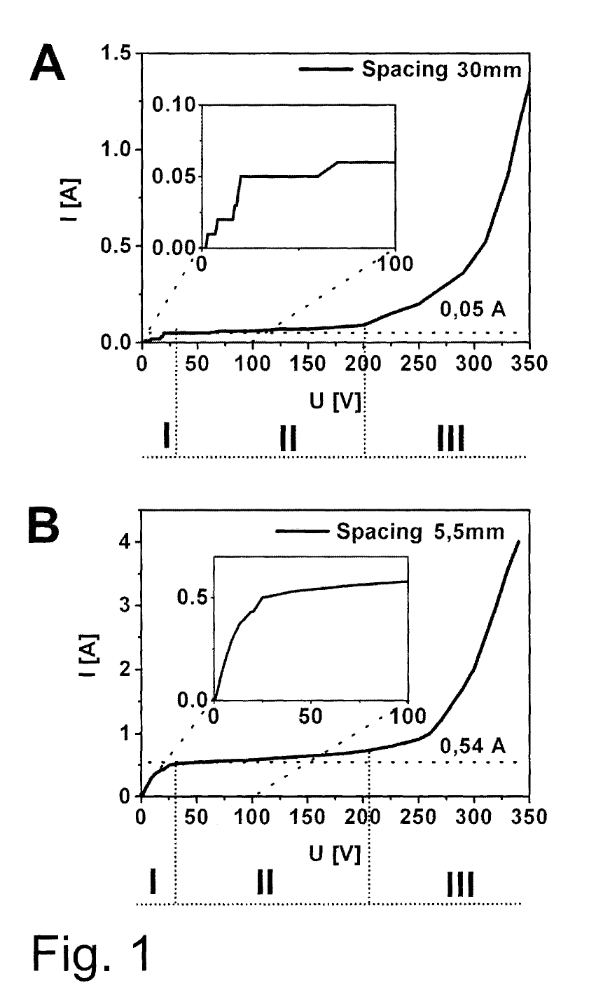

If a voltage is now applied to the electrodes, then a current flows between the electrodes through the plasma. The course of the current as a function of the voltage is represented in FIG. 1 by way of example. It can be subdivided into three regions. In the case of small voltages, the region I in which the current flow rises steeply is observed. The steep rise in this region corresponds in a first approximation to a Langmuir probe measurement with a symmetrical double probe. The charge carrier density and electron temperature is measured here in the immediate vicinity of the electrode. In the double probe measurement, the level corresponds in a very good approximation directly to the ion saturation current defined below, from which the charge carrier density can also be determined with knowledge of the electron temperature and the mass of the positive ions.

Upon increasing the voltage further, there follows region I a region II in which the current flow does not rise or almost not with increasing voltage. The current flow in this region which is therefore essentially the same for all voltages of region II, is termed ion saturation current. The ion saturation current can be used as a measure of the plasma excitation above the cathode.

Following region II, with a further increase in the voltage applied between the electrodes, is a region III with a renewed increase in current flow. This rise can be attributed to electron multiplication effects which, on the one hand, are effected by a higher secondary ion production in the gas phase and, on the other hand, by a higher secondary electron yield at the cathode on which increasingly energy-rich positive ions impinge. The diamond nucleation takes place in this region III.

It should be noted here that the region II is crucial for characterisation of the plasma, in which region however still no diamond nucleation takes place. The ion saturation current measured in this region is a plasma property. By means of this, the plasma above the substrate can be characterised, with which plasma diamond nucleation is possible in region III.

FIG. 1 shows the three regions by way of example. FIGS. 1A and 1B hereby differ from each other by the spacing of the electrode plates. In FIG. 1A, the electron spacing is 30 mm and in FIG. 1B it is 5.5 mm. The regions I, II and III can be identified in both Figures.

In FIG. 1A, the current flow rises steeply to approx. 30 V with the applied voltage. The region of this rise is region I. For applied voltages between 30 and 200 V, the current flow through the plasma is essentially constant and, in the illustrated example, is approx. 0.05 A. This region of the constant current flow is the above-described region II and the adjusting current strength of 0.05 A is the ion saturation current. For applied voltages greater than approx. 200 V, the current flow in region III again rises with rising voltage.

The three regions can also be differentiated in FIG. 1B. The ion saturation current here is approx. 0.54 A. There follows here also region III in which the current strength again rises greatly. In this region III, the diamond nucleation is implemented.

The dependency of the ion saturation current upon the spacing of the electrode plates can also be detected well in FIGS. 1A and 1B. With a spacing of 30 mm, the ion saturation current, as shown, is only 0.05 A whilst, at a spacing of 5.5 mm, it is at 0.54 A. It is now hereby crucial that, for example with a spacing of 30 mm, a diamond nucleation is not possible in a satisfactory manner whilst it is possible for example in the arrangement shown in FIG. 1B.

In the case of the measurements shown in FIG. 1, a copper anode with a diameter of d=118 mm and an area of A=10,900 mm² was used. On the cathode, an iridium layer was situated with a diameter of d=100 mm and an area of A=7,800 mm². The microwave frequency was at 2.45 GHz, the radiated microwave power was 2.1 kW.

The knowledge now underlying the present invention is that a diamond nucleation on iridium is also possible if the ion saturation current divided by the area of the cathode, i.e. the ion saturation current density, is equal to or greater than 0.001 A/cm². The ion saturation current density can hereby be determined as described above.

It is attempted in the following to find a possible explanation for the increase in ion saturation current and the meaning thereof for the nucleation of diamond without wishing herewith however to make a claim as to correctness.

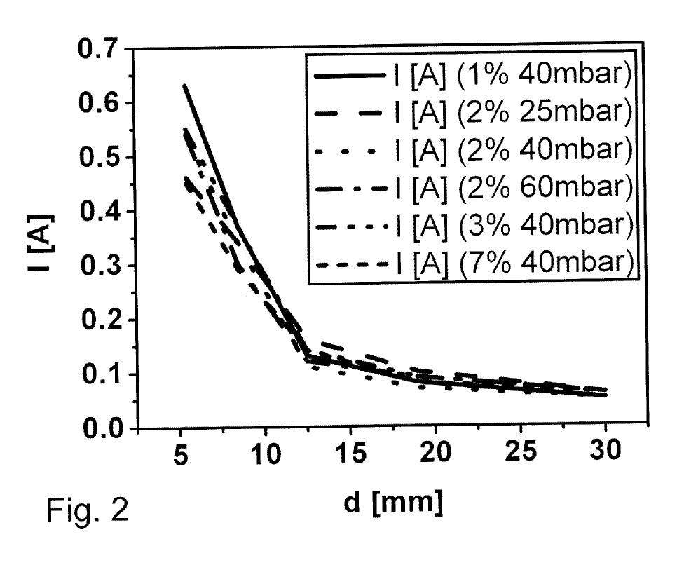

FIG. 2 shows the saturation current in the saturation region, i.e. in region II, with a voltage of approx. 100 volts. The values of the current in FIG. 2 therefore correspond to the approx. constant currents of region II in FIG. 1. The spacing d of the electrode plates from each other is hereby varied between 5.5 and 30 mm. As also in FIG. 1, a copper anode with a diameter of 118 mm and an area of A=10,900 mm² and also an iridium layer of 100 mm and an area of 7,800 mm² was used here.

It is detected clearly in FIG. 2 that the reduction in plate spacing of 30 mm to 5.5 mm results in a rise in saturation current by approx. one order of magnitude. The effect hereby can be observed mainly below 15 mm. This attests to a higher plasma activation (ion/electron density) directly above the cathode. In order to understand this effect, it is helpful to imagine what happens when a microwave plasma is brought in contact with a surface.

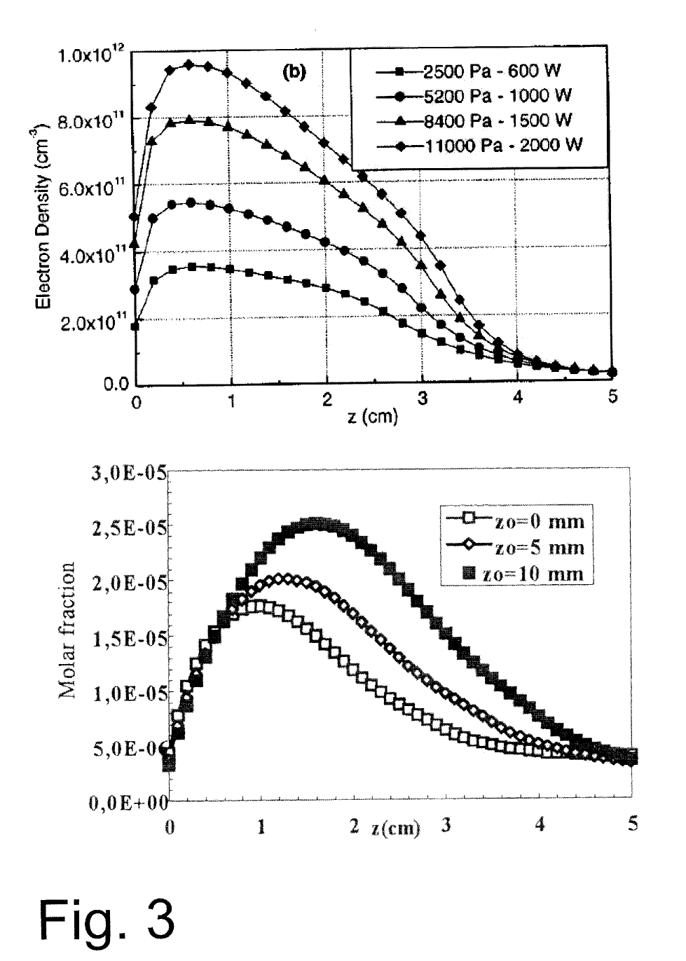

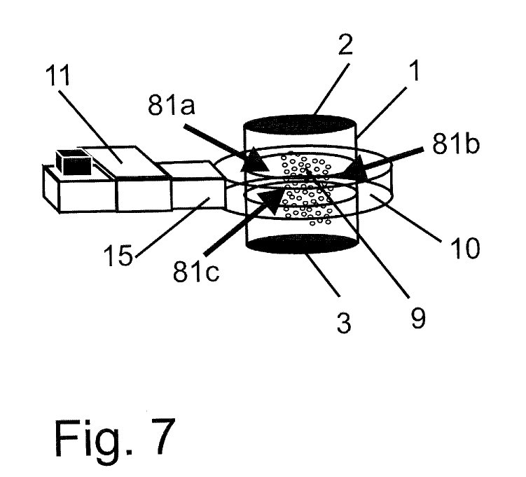

FIG. 3 shows the calculated profiles of the electron density above a substrate which is disposed at position z=0 cm. The curves of the left partial picture were calculated for 390 watts at 2500 Pa and are taken from K. Hassouni et al. in Handbook of Industrial Diamond and Diamond Films, Ed. M. A. Prelas, G. Popovici, L. K. Bigelow (Marcel Dekker, New York, 1998) chapter 18, p. 697 ff. FIG. 7.1.11). The right partial picture originates from K. Hassouni, T. A. Grotjohn, A. Gicquel, J. Appl. Phys. 86 (1999) 134. It is detected that the electron density drops drastically towards the substrate. This is inter alia a consequence of the fact that each charge carrier which impinges on the surface is neutralised by the latter (with electrons these are absorbed). The transition, in the left and right partial picture of FIG. 3, is of different widths (1 to 2 cm in the left partial picture).

The width of the space charge responsible for the ion bombardment during the nucleation process is, in contrast, at less than 1 mm. Hence the value of the space charge density directly on the surface is crucial.

If a small sample is now placed in the plasma, the influence thereof on the plasma density is significantly less than for a large sample. Lowering the charge carrier density on the sample surface turns out hence to be significantly lower, which also results in higher ion saturation currents and in diamond nucleation which has frequently proved to be successful on small Ir samples.

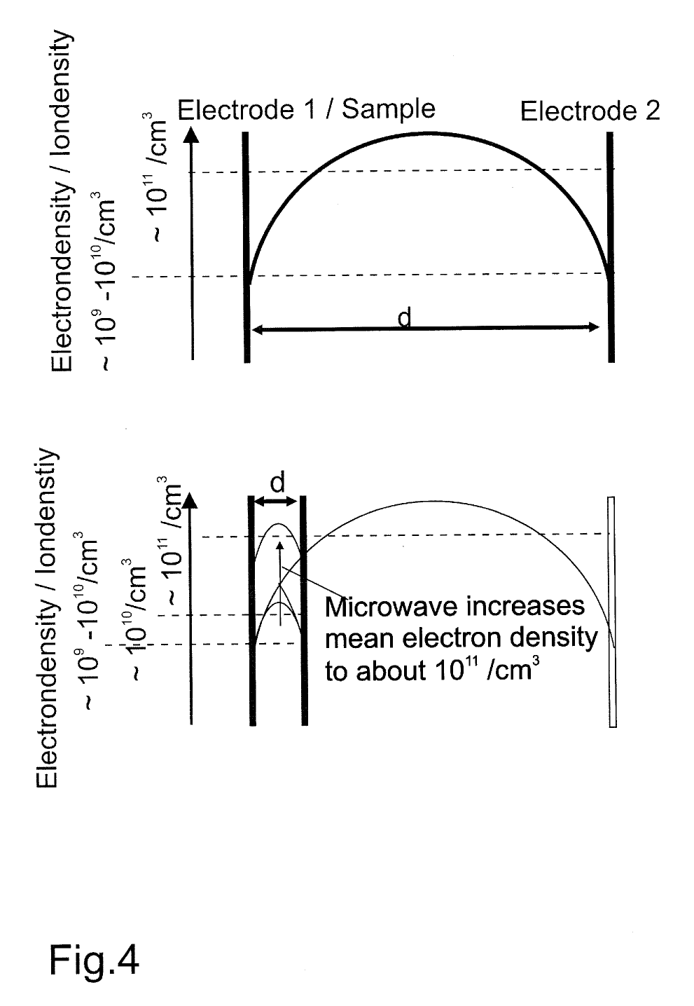

In the case of large-area samples, a course of the charge carrier density as represented in FIG. 3 should however be assumed. This applies both for the cathode and for the oppositely situated anode. If both are now brought closer together, then the average charge carrier density within the parallel plate arrangement would be lowered with a maintained value at the surface, as represented in FIG. 4. FIG. 4 shows a model proposal for the change in plasma ionisation in a parallel plate arrangement with two different plate spacings. The upper partial picture here shows a large spacing, for example 3 to 8 cm, whilst the lower partial picture shows a small spacing of for example less than 2 cm. The reduced screening by the lower charge carrier density leads to higher penetration of the microwave field so that ultimately the entire course of the curve moves upwards and in particular the plasma density on the surface is significantly increased. The numeric values for the charge carrier densities should thereby be understood merely as relative values.

An altered field distribution in the parallel plate arrangement might be considered as a further cause of the higher plasma excitation at the cathode.

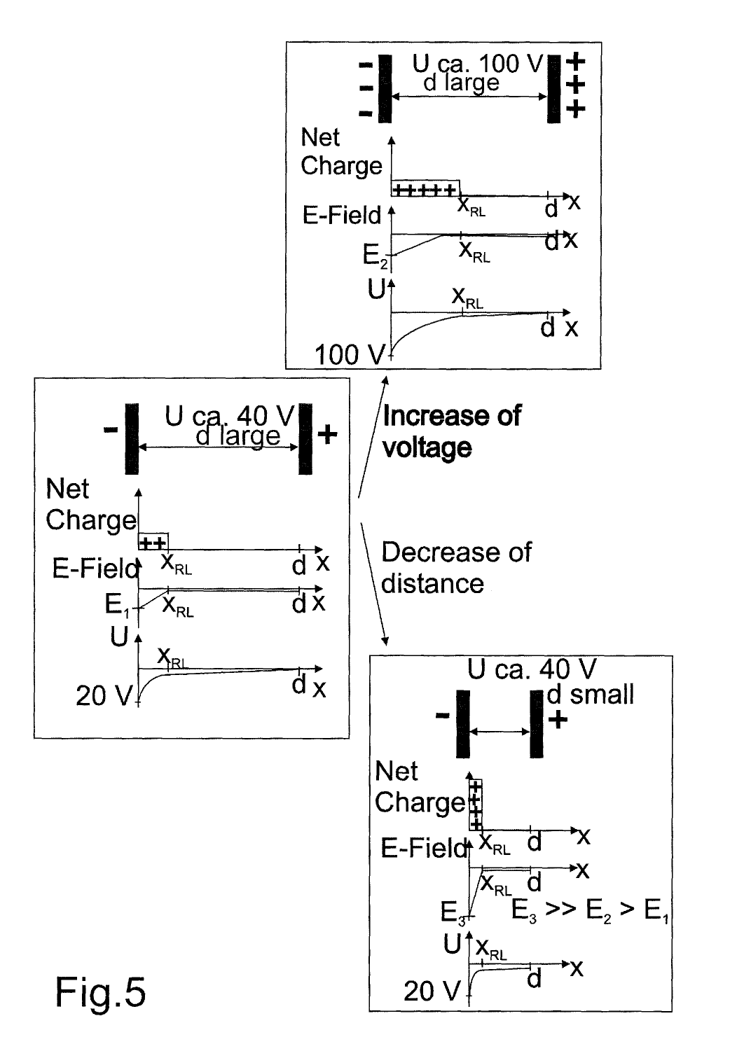

FIG. 5 shows the schematic representation of the space charges in the boundary layer when applying a direct voltage (bias voltage). In the case of small voltages, firstly the negative charge carriers are displaced from the edge layer above the cathode. A positive space charge remains. This extends with increasing voltage. For a prescribed voltage drop U, the field strength E on the surface rises with the charge carrier density (∝ ρ^{1/2}). This means that the higher the ionisation of the plasma above the substrate, the more easily can the ion bombardment conditions required for the diamond nucleation on the surface be achieved.

Alternatively if the voltages are increased in order to achieve the necessary currents, then this leads to instabilities.

According to the invention, an ion saturation current density of equal to or greater than 0.001 A/cm² is now produced in a plasma reactor with at least one anode and one cathode, which have a flat configuration and are delimited respectively by an edge. This edge should be understood here geometrically as the delimitation of the corresponding surface. The anode is orientated with one surface towards a surface of the cathode. Between the surfaces of the electrodes, i.e. between anode and cathode, which surfaces are orientated towards each other, the region in which a plasma can be produced is situated. This region is subsequently termed plasma region. A gas can be introduced into the plasma region between the surfaces of the electrodes.

The plasma reactor according to the invention has in addition a device for supplying microwaves with which microwaves of one or more frequencies can be radiated between the electrodes into the plasma region. The microwaves thereby introduce a power which contributes to the plasma production into the plasma region, i.e. they contribute to the ionisation of the gas present in the plasma region.

It is now crucial that a plasma with an ion saturation current density of equal to or less than 0.001 A/cm² can be produced with the plasma reactor in the plasma region. This can be achieved in that the spacing between the electrodes of the plasma reactor is chosen to be sufficiently small. In addition, a microwave with a suitable frequency and power is radiated. According to the invention, different combinations of electrode spacing, microwave frequency and microwave power lead here to an ion saturation current density of equal to or greater than 0.001 A/cm². Thus the mentioned value can be achieved for example, on the one hand, by a low microwave frequency and a small spacing of the electrode surfaces relative to each other but, on the other hand, also by a higher microwave frequency and a greater spacing. It is possible with a maintained spacing to increase the microwave frequency in order thus to achieve the mentioned value of the ion saturation current density. On the other hand, it is possible with a maintained microwave frequency to reduce the spacing of the electrode plates relative to each other in order thus to achieve the mentioned value of the ion saturation current density. The correct determination of the mentioned parameters is however possible without difficulty with the help of the above-described measurement of the ion saturation current density.

Basically the case is that it is advantageous for the diamond nucleation if the ion saturation current density is greater. It is therefore advantageous if the spacing between the electrodes is so small and/or the power and/or the frequency of the radiatable microwaves is chosen such that a plasma with an ion saturation current density of equal to or greater than 0.0015 A/cm² is produced by the radiation of the microwaves in the plasma region. It is even more advantageous to produce correspondingly a plasma with a saturation current density of equal to or greater than 0.002 A/cm², preferably greater than or equal to 0.003 A/cm², preferably greater than or equal to 0.005 A/cm².

Advantageously, anode and cathode are orientated, situated one opposite the other, in planes parallel to each other. The edges of the corresponding surfaces are hereby situated in planes which are parallel to each other. Anode and cathode are therefore disposed adjacently such that the surfaces in one projection overlap in a direction perpendicular to the surface of the electrodes at least partly. The gap between anode and cathode is, as described, preferably very small, i.e. involving preferably a microwave discharge with an aspect ratio (width/height) of greater than 5, overlaid by a DC discharge.

The edges of the electrodes can be circular. It is advantageous in order to achieve the mentioned values for the ion saturation current density in this case if the diameter of the electrodes, i.e. of the anode and/or of the cathode, divided by the spacing of the electrodes from each other (i.e. the aspect ratio) is greater than or equal to 3, preferably greater than or equal to 4, preferably greater than or equal to 5.

The present method is precisely suitable for large-area coating with diamond. Anode and/or cathode and/or the wafer can therefore be greater than 3 cm, greater than 5 cm, greater than 8 cm or even greater than 10 cm. Preferably, the electrodes are however smaller than 16 cm, preferably smaller than 14 cm, preferably smaller than 12 cm. It is also possible that the anode is slightly larger than the cathode.

The microwaves which can be radiated into the plasma region are preferably at a frequency between 915 MHz and 30 GHz. The frequencies 915 MHz, 2.45 GHz and 30 GHz for which microwave generators are available are hereby particularly preferred.

The spacing of the electrodes from each other is also of particular importance, for which reason this is preferably less than 2 cm, preferably less than 1.5 cm, preferably less than 1 cm or less than 0.5 cm. However, the spacing should preferably be greater than 0.05 cm. A spacing of the electrodes of approx. or equal to 1 cm is particularly suitable. When reducing the spacing to below 10 mm, the charge carrier density in the edge layer of both plates can be increased by an order of magnitude.

In order to achieve as uniform a nucleation as possible, it is advantageous if the microwaves are radiated centrally-symmetrically into the plasma region. This means that the microwaves can be radiated in from several directions in the direction of the centre of the plasma region with the same intensity and preferably also the same phase. In the case of plate-shaped electrodes, the radiation directions of the microwaves should preferably extend in a plane parallel to the plane of the electrode plates.

Preferably, a dielectric window, such as e.g. a quartz window, is disposed between the plasma region and the device for supplying microwaves. As a result, the pressure of the gas in the plasma region can be changed.

One or more waveguides are particularly suitable as device for supplying the microwaves, said waveguides having openings which are directed towards the centre of the electrodes or of the plasma region. The openings are preferably slot-like and extend preferably azimuthally.

The openings are disposed adjacently in the waveguide preferably in the direction parallel to the edges of the electrodes at a spacing of the maxima of the resonator modes of the microwaves in the waveguide. Each opening then lies therefore at the position of a maximum of the microwave in the waveguide. The openings are preferably disposed at equal spacings relative to each other.

The waveguide preferably extends with its longitudinal direction parallel to the edges of the electrodes. It is hereby preferably at a slight spacing from these edges in order to leave room for a possibly present quartz window. It should hereby be taken into account in particular that a lower pressure prevails within the quartz tube than outwith so that the breakdown field strength there is significantly lowered. If the quartz tube is brought too close to the openings then a plasma ignites directly on the quartz tube, which is not desired.

In addition to the described waveguide extending along the edge of the electrodes, also other possibilities are feasible for supplying the microwave to the plasma region. Such an alternative possibility resides in disposing the cathode in a cavity in such a manner that the edge of the cathode surface has a preferably essentially constant spacing from the wall of this cavity. The cavity has an opening for supplying microwaves under the centre of the cathode and is sealed from the anode on the side situated opposite this opening. The microwaves are introduced here into the cavity therefore through the mentioned opening, then impinge on the side of the cathode orientated away from the anode and circulate around the cathode around the edges thereof, i.e. between the edges of the cathode and the walls of the cavity. They therefore arrive centrally-symmetrically in the plasma region between the cathode and the anode.

In order to produce the plasma in the plasma reactor according to the invention, it is preferred if the microwave has a power between 0.5 and 3 kW, preferably between 1 and 2 kW. The power density introduced by the microwave is preferably between 5 W/cm² and 50 W/cm², preferably at 20 Wcm².

The direct voltage which can be applied in the plasma reactor according to the invention between the electrodes is chosen preferably so large that the power introduced by this direct voltage into the plasma is of the same order of magnitude or equally as great or less than the power introduced by the microwave into the plasma, for example respectively approx. 10 to 20 W/cm² for microwave and direct voltage. A glow discharge for instance is then present in combination with a microwave discharge.

Voltages between 100 V and 500 V, preferably between 200 V and 400 V, are hereby particularly suitable.

The gas which can be introduced into the plasma region is then of particular importance, said gas being ionised for plasma production. The gas hereby has preferably a carbon-containing component, such as e.g. methane. It is preferred if an excess of hydrogen of 80 to 99% is present in the gas. Furthermore, the gas can contain small or medium quantities of argon, nitrogen or oxygen. The pressure is preferably in the range between 20 and 200 mbar.

The property of a wafer is now intended to be explained subsequently, said wafer being able to be provided in the plasma reactor according to the invention with nucleation nuclei and a diamond layer.

Such a wafer preferably has a layer system with a substrate layer comprising monocrystalline silicon, at least one buffer layer disposed thereon and also at least one metal layer disposed thereon comprising a high-melting material.

The substrates, such as silicon, are available over a large area and have in particular a good thermal fit to diamond. As a result, the thermal stress during cooling of an applied diamond layer is minimised and the adhesion is optimised. Such substrates are economical and available with large areas. Deposition of the buffer layer, mainly oxides, such as e.g. strontium titanate, yttrium-stabilised zirconium oxide, cerium oxide or also silicon carbide, can be effected for example by means of vacuum methods, MBE, PLD, CVD or PVD.

Oxides, as indicated above, enable good adhesion of metal layers deposited thereon, in particular iridium layers. It is therefore possible to deposit quasi monocrystalline iridium layers on these buffer layers with suitable methods, such as for example electron beam deposition or sputtering. Interestingly, it emerged hereby that the metal layers can be quite substantially better orientated than the buffer layers situated thereunder. The reason for this is that the buffer layers can typically still have large faulty orientations of >2°, >1° or even >0.5°, whilst the applied iridium layers are of high quality and monocrystalline or quasi monocrystalline, for example with a faulty orientation <0.5° or <0.2°.

Furthermore, the produced quasi monocrystalline iridium layers adhere on this substrate and the produced diamond layers are excellent because of the good thermal fit between diamond and silicon. In particular with suitable process management, i.e. with slow deposition of the metal layer on the buffer layer, the metal layer can be very substantially better orientated than the buffer layer situated thereunder. Buffer layers of this type, in particular TiN, CeO₂, YSZ (yttrium-stabilised zirconium oxide), Y₂O₃, MgO, strontium titanate (SrTiO₃) and the like, as are known for deposition of high-temperature superconductor layers on silicon, typically still have large faulty orientations of >1°, but can now serve nevertheless as base for growing quasi monocrystalline or monocrystalline metal layers.

A wafer which has an Ir/metal oxide/silicon layer system is particularly preferred, the metal oxide comprising or consisting of SrTiO₃ or yttrium-stabilised zirconium oxide (YSZ). The crystallographic surfaces of substrate, buffer layer and/or metal layer, i.e. in this case of Ir, metal oxide and/or silicon, are hereby (001) or (111). Preferably, the crystallographic surfaces of the mentioned layers are the same. However, at least the metal layer has particularly preferably the mentioned crystallographic surfaces or this orientation. The metal layer is of particularly practical importance because it establishes the orientation of the diamond layer growing thereon. The deviations from this preferred orientation can be between 0 and 10°. Metal layers with virtually or essentially monocrystalline orientation are preferred, the mosaicity of which (tilting and twist) is very low, preferably <1°. The metal layers can also be fibre-textured (solid support surface but in-plane without preferential direction). With respect to the dimensions of the electrodes, it is preferred if the area of the anode is substantially equal to or exactly equal to the area of the cathode. However, it is also possible that the anode is larger than the cathode.

In order to prevent ignition of the plasma on the sides of the electrodes orientated away from the plasma region, the reactor space in these regions orientated away from the plasma region should be continued by a hollow or solid metal cylinder, the cross-sectional areas of which have the same or similar dimensions to the corresponding electrode. Below the sample, the sample holder can instead also fill the space.

Further possibilities exist for configuration of the electrodes. In particular the shape of the surfaces of the electrodes is variable.

Firstly, the plasma reactor can be constructed with flat electrodes. Therefore the surfaces of the electrodes orientated towards each other are then flat. However, it is also possible to configure the electrodes with surfaces which deviate from a flat shape. It is possible in this way to form the plasma region and the plasma present in said plasma region. In detail, the plasma excitation and field distribution and hence also the local ion bombardment can be influenced. In addition, the hydrodynamic conditions in the gas phase can be influenced favourably by the structuring of the anode. It is hereby particularly preferred if the surface of the cathode is flat and the surface of the anode has a continuous depression towards the centre so that the surface of the anode is situated closer to the cathode towards the edge than in the centre.

Alternatively, the anode can also have a preferably rounded-off, obtuse angle so that it is closer to the cathode towards the centre in all directions.

In addition, it is advantageous if the temperature of cathode and/or anode is controllable and/or adjustable separately. As a result, it is possible to control the flow ratios between the plates.

A further advantageous embodiment resides in disposing a gas supply in the centre of the anode.

Finally, the plasma reactor according to the invention preferably also has a microwave generator or a microwave emitter with which microwaves of at least one frequency can be produced and can be conducted into the device for supplying microwaves. The microwaves are therefore produced by the microwave generator or emitter and conducted from the device for supplying microwaves such that they radiate in the desired manner into the plasma region between the electrodes.

In addition to the above-described plasma reactor, the invention also relates to a method for nucleation of diamond on at least one wafer. The wafer is hereby disposed between a flat anode and a flat cathode and a plasma is produced in the region between the wafer and the anode, i.e. the plasma region, the ion saturation current density of which plasma is greater than or equal to 0.001 A/cm². For this purpose, at least one gas containing a carbon source is introduced into the plasma region between the electrodes and a direct voltage is applied between the electrodes such that the electrical field consequently produced between anode and cathode permeates the gas present in the region. At the same time, microwaves are radiated into the gas.

All the data relating to the dimensions and sizes which are described above for the plasma generator and also advantageous embodiments apply analogously for the method according to the invention. In particular, it is advantageous for the method according to the invention to use the above-described plasma reactor in one of its possible embodiments.

It is therefore possible by means of the plasma reactor according to the invention and the method for nucleation to vary the cathode edge layer and hence the ion bombardment of the surface over a large area, homogeneously and in a stable manner over a large voltage range. It is hence possible to adjust the current densities required for the diamond nucleation reproducibly, to nucleate diamond epitaxially on iridium over an area larger than 7000 mm² and subsequently to grow a monocrystalline layer thereon.

The invention is intended to be explained subsequently in more detail with reference to a few examples.

There are shown:

FIG. 1A the current flow through a plasma as a function of the applied voltage at an electron spacing of 30 mm,

FIG. 1B the current flow through a plasma as a function of the applied voltage at an electron spacing of 5.5 mm,

FIG. 2 the ion saturation current as a function of the spacing of the electrodes from each other for various gas compositions and pressures,

FIG. 3 calculated profiles of the electron density above a substrate,

FIG. 4 a model for the change in plasma ionisation in a parallel plate arrangement when the plate spacing is reduced with microwave excitation,

FIG. 5 a schematic representation of the space charges in the edge layer when applying a bias voltage,

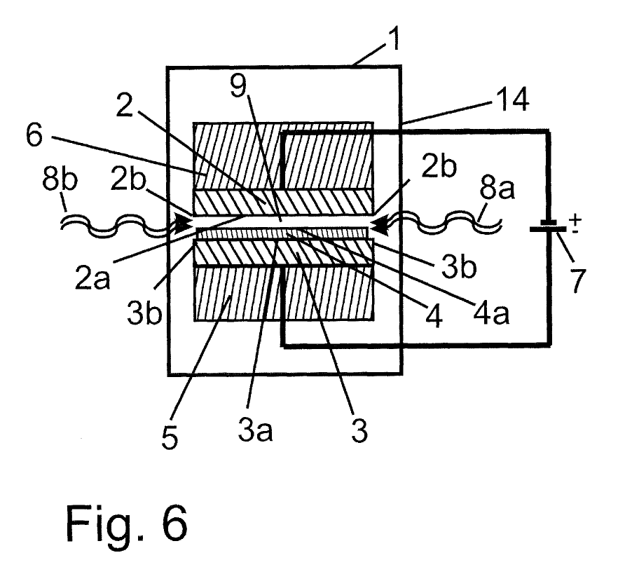

FIG. 6 a plasma reactor according to the present invention,

FIG. 7 an example of a device for supplying microwaves and

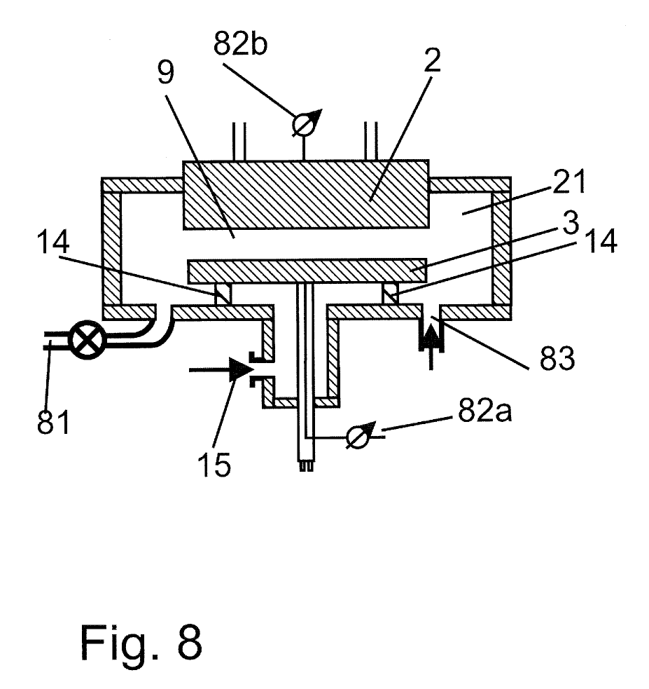

FIG. 8 an alternative embodiment of the plasma reactor corresponding to the present invention,

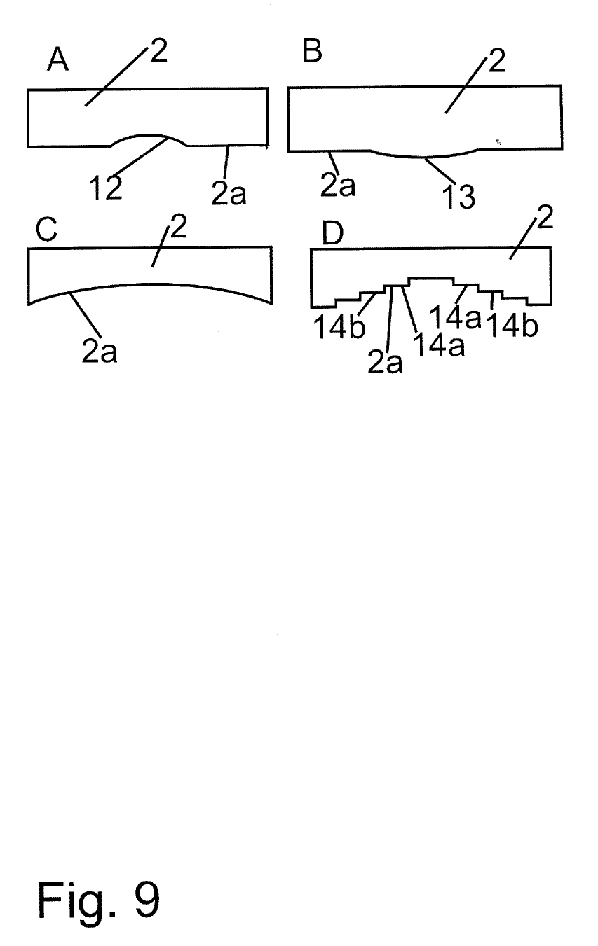

FIG. 9A to D possible non-flat shapes of the anode,

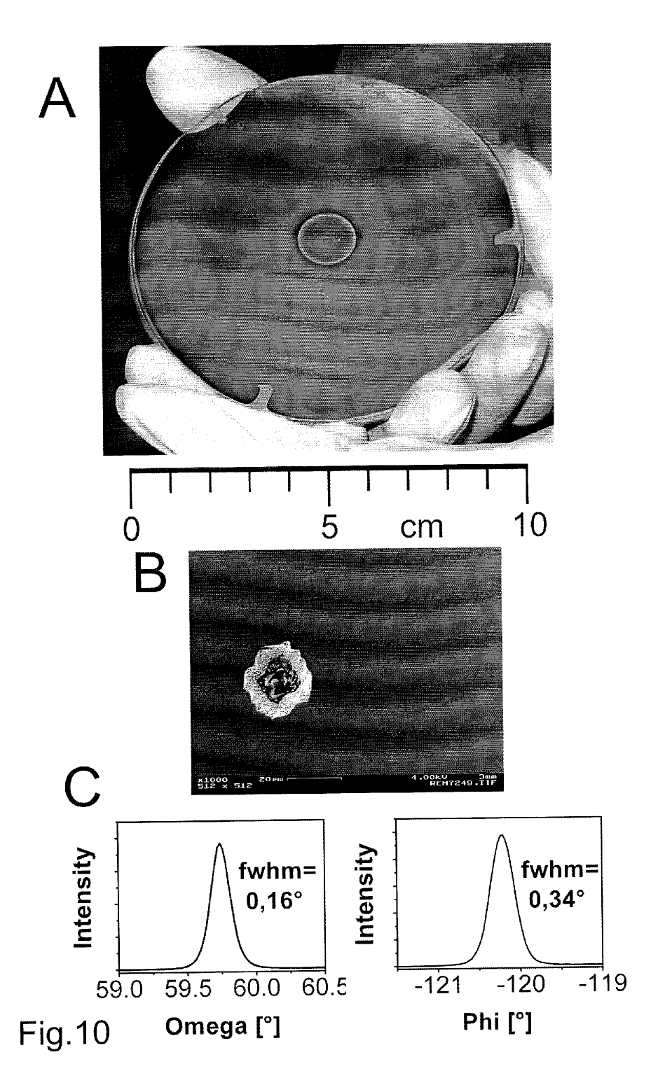

FIG. 10A a wafer coated according to the method according to the invention,

FIG. 10B a scanning electron microscopic picture of a wafer nucleated analogously to FIG. 10A and subsequently grown,

FIG. 10C the tilt of the coating of the wafer of FIG. 10B,

FIG. 10D the twist of the coating of the wafer of FIG. 10B and

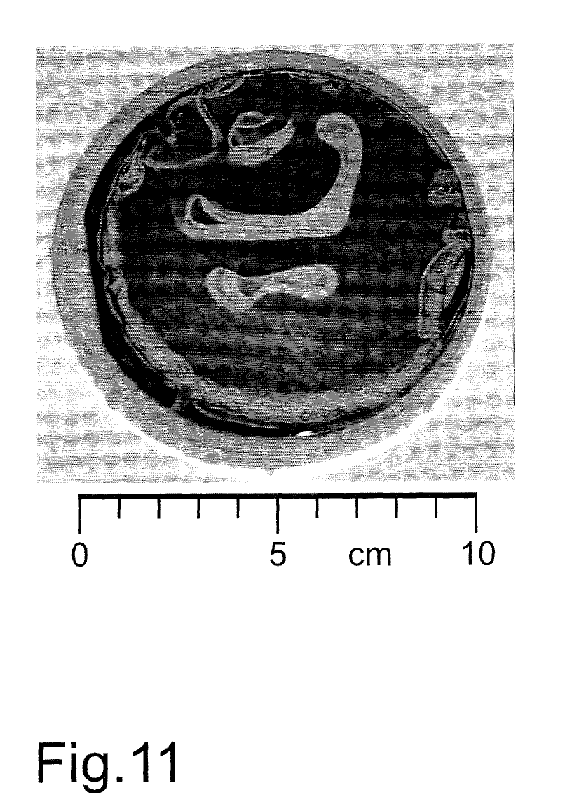

FIG. 11 a sample produced purely by means of DC discharge without microwaves.

FIG. 6 shows a possible embodiment of a plasma reactor 1 according to the present invention. The plasma reactor 1 has two flat electrodes 2 and 3 which have surfaces 2a or 3a orientated towards each other and are delimited respectively by an edge 2b or 3b. A plasma region 9 is present between the surfaces 2a and 3a of the electrodes 2 and 3, into which plasma region a gas can be introduced. Via a device, not represented in FIG. 6, for supplying microwaves, microwaves 8a, 8b can be radiated into the plasma region. The microwaves 8a, 8b contribute to the ionisation of the gas present in the plasma region 9. According to the present invention, the spacing between the electrodes 2 and 3 or the surfaces of the electrodes 2a and 3a which are orientated towards each other or the surface 2a of the anode 2 and the surface 4a of the wafer 4 is now chosen such that, by radiation of the microwaves 8a, 8b in the plasma region 9, a plasma with an ion saturation current density of equal to or greater than 0.001 A/cm² can be produced. In addition to the spacing of the electrodes or alternatively thereto, the power and/or the frequency of the radiated microwaves 8a, 8b can be chosen suitably in order to produce a plasma with the mentioned ion saturation current density. In the illustrated example, the electrodes 2 and 3 have a flat configuration, i.e. the surfaces 2a and 3a are flat. The width of the gap between the electrodes in the illustrated example is 1 cm, the diameter of the electrodes is 12 cm. However, it can also be smaller or larger. Respectively a metal cylinder 5 or 6 is disposed here on the sides of the electrodes 2 and 3 orientated away from the plasma region, said metal cylinder being able to be hollow or solid and having a similar diameter to the corresponding electrode 2 or 3. The anode 2 and the metal cylinder 6 can hereby also comprise one piece. The entire arrangement of the electrodes with the wafer 4 and the metal cylinders 5 and 6 is accommodated in a vacuum chamber which is surrounded by a quartz glass cylinder 14.

The mentioned spacing is preferably less than 2 cm, e.g. 1 cm. The anode 2 can have or comprise for example copper and e.g. have a diameter of d=118 mm with an area of A=10,900 mm². The cathode can have for example an iridium layer with a diameter of d=100 mm with an area of A=7,800 mm². For nucleation of diamond on the surface 4a of the wafer 4, a voltage is now applied by the voltage source 7 between the anode 2 and the cathode 3. For nucleation, this voltage is in the range between 100 V and 300 V or even higher. The microwaves 8a, 8b are preferably radiated from several directions. In FIG. 6, only two directions situated in the drawing plane are illustrated, however the microwaves can also be radiated in addition from directions not situated in the drawing plane.

FIG. 7 now shows a possible embodiment of a device 15 for supplying microwaves 8a, 8b and 8c into the plasma region 9. The arrows 81a, 81b and 81c hereby indicate roughly the direction in which the microwaves are radiated. The microwaves are produced firstly in the device shown in FIG. 7 in a microwave generator (not shown) and then introduced into an annular waveguide 10 which has slot-like openings (antenna slots) towards the plasma region 9. The microwaves are fed into the annular waveguide and enter through the openings into the plasma region 9. The slots are disposed respectively at the spacing of the maxima of the resonator modes.

FIG. 8 shows an alternative embodiment of the plasma reactor according to the present invention. The cathode 3 is hereby disposed in a cavity 21 into which a gas can be introduced via a supply line 83. The gas can be withdrawn by the line 81. Opposite the cathode, an anode 2 is disposed such that it seals the space 21. Microwaves can now be supplied to the space 21 via a device 15 for supplying microwaves. The microwaves then impinge firstly on the rear-side of the cathode 3 and are introduced around the latter through the quartz glass cylinder 14 into the plasma region 9. On the side of the cathode 3 orientated towards the anode 2, a wafer 4 is disposed. Again the spacing between cathode 3 and anode 2 is chosen such that the ion saturation current density is at least 0.001 A/cm².

In the illustrated example, the temperature of the cathode 3 can be controlled via a temperature control 82a. The temperature of the anode 2 can be controlled via the temperature regulator 82b.

Finally, FIG. 9 shows, in the partial Figures A to D, various possible embodiments of the anode deviating from the flat shape by means of which the plasma can be formed in a desired manner. Thus the anode 2 shown in FIG. 9A has a pool 12 in the middle thereof. If the anode 2 is circular, then the pool 12 in the plane of the anode underside 2a is also circular.

An alternative embodiment of the anode is shown in FIG. 9B. Here, the anode 2, on the underside 2a thereof, has a raised portion 13 relative to the corresponding surface thereof. Here also, in the case where the anode 2 is circular, the raised portion 13 is circular in the cross-section thereof in the underside 2a.

A further possible anode shape is shown in FIG. 9C. The anode 2 is configured here such that the underside 2a of the anode 2 comes continuously closer to a cathode 3 disposed below this anode 2 towards the edge. Alternatively, the anode 2, with the underside 2a thereof, also can continuously come closer to a cathode 3 towards the centre. The underside 2a can also have a convex or concave configuration. These shapes are also preferably radially-symmetrical about the centre of the anode 2.

FIG. 9D shows a further embodiment of the anode 2a which can likewise have a convex or concave configuration. In the illustrated case, the anode 2a, with the underside 2a thereof, comes closer to a cathode 3 disposed parallel below the latter towards the edges thereof, discontinuously in steps. This embodiment is also preferably radially-symmetrical about the centre of the anode, which means that the steps 14a, 14b etc. are annular.

FIGS. 10A to 10D show tests of a successful embodiment. The wafer shown in FIG. 10A was nucleated here firstly at a pressure of 40 mbar, a microwave power of 2,100 W and a gas mixture of 490 sccm hydrogen and 10 sccm methane at a substrate temperature of 850° C. for 25 min. The bias voltage thereby was 300 V, the DC current 2.5 A and the spacing Ir layer/anode 8.5 mm. Thereafter, it was grown at 25 mbar, 2,100 W microwave power with 5 sccm methane, 0.4 sccm nitrogen in 494 sccm hydrogen for 60 min at 700° C. The thickness of the diamond layer after this growth step was 250 nm. The area of epitaxial diamond on the 100 mm wafer was greater than 70 cm² (only the inner ring with approx. 1.5 cm diameter was unorientated).

After 70 h growth on a further sample which was nucleated and grown otherwise correspondingly to FIG. 10A, the scanning electron micrograph in FIG. 10B and also the texture measurement in FIG. 10C which shows the tilt, and the texture measurement in FIG. 10D which shows the twist were produced. The microscope picture in FIG. 10B was taken at a place with a defect since structures can scarcely still be detected on the perfectly grown-together surface. The defect served here for focusing and comparison of the coated surface. In the Figure, the high homogeneity of the coating can be detected readily.

FIG. 11 shows a sample which was produced purely by means of a DC discharge without microwave. The nucleation was implemented for 7 min at 100 mbar, an electrode spacing (wafer surface-anode) of 2 mm, a substrate temperature of 800° C. and a gas mixture of 380 sccm hydrogen and 20 sccm methane. The DC voltage was 440 V, a current strength of 3 A being produced. Thereafter, the nucleation layer was grown further for 60 min at 1,600 W microwave power, a pressure of 30 mbar, 760° C., 469 sccm hydrogen and 5 sccm methane in a microwave unit. As can be detected clearly in FIG. 11, very non-homogeneous layers with unorientated diamond and defects which originated from arc discharges were produced.

Finally, the third configuration must also be mentioned: direct voltage in conjunction with microwave at a large spacing of the electrodes (2-4 cm). In general, no nucleation of diamond resulted.

1-55. (canceled)

56. A plasma reactor, comprising:
at least two flat electrodes having surfaces orientated towards each other, the electrodes being delimited respectively by an edge;
a plasma region producing a plasma between the surfaces of the electrodes with an ion saturation current density of equal to or greater than 0.001 A/cm2, wherein a gas is introduced into the plasma region; and
a device supplying microwaves having at least one frequency, the microwaves radiating into the plasma region and introducing a power into the plasma region contributing to the plasma production, at least one of (a) a spacing between the electrodes, (b) the power of the microwaves, and (c) the frequency of the microwaves being selected to maintain the ion saturation current density of equal to or greater than 0.001 A/cm2.

57. The plasma reactor according to claim 56, wherein the electrodes includes an anode and a cathode.

58. The plasma reactor according to claim 56, wherein an ion saturation current density of equal to or greater than 0.0015 A/cm2 is maintained by controlling at least one of (a) a spacing between the electrodes, (b) the power of the microwaves, and (c) the frequency of the microwaves.

59. The plasma reactor according to claim 56, wherein an ion saturation current density of equal to or greater than 0.002 A/cm2 is maintained by controlling at least one of (a) a spacing between the electrodes, (b) the power of the microwaves, and (c) the frequency of the microwaves.

60. The plasma reactor according to claim 56, wherein an ion saturation current density of equal to or greater than 0.003 A/cm2 is maintained by controlling at least one of (a) a spacing between the electrodes, (b) the power of the microwaves, and (c) the frequency of the microwaves.

61. The plasma reactor according to claim 56, wherein an ion saturation current density of equal to or greater than 0.005 A/cm2 is maintained by controlling at least one of (a) a spacing between the electrodes, (b) the power of the microwaves, and (c) the frequency of the microwaves.

62. The plasma reactor according to claim 58, wherein the anode and the cathode are situated one opposite the other and orientated in planes parallel to each other.

63. The plasma reactor according to claim 56, wherein the edges of the electrodes are circular.

64. The plasma reactor according to claim 63, wherein a diameter of the electrodes divided by the spacing between the electrodes is greater than or equal to 3.

65. The plasma reactor according to claim 63, wherein a diameter of the electrodes divided by the spacing between the electrodes is greater than or equal to 4.

66. The plasma reactor according to claim 63, wherein a diameter of the electrodes divided by the spacing between the electrodes is greater than or equal to 5.

67. The plasma reactor according to claim 63, wherein a diameter of the electrodes divided by the spacing between the electrodes is greater than or equal to 10.

68. The plasma reactor according to claim 63, wherein a diameter of at least one of the electrodes is greater than 3 cm.

69. The plasma reactor according to claim 63, wherein a diameter of at least one of the electrodes is greater than 5 cm.

70. The plasma reactor according to claim 63, wherein a diameter of at least one of the electrodes is greater than 8 cm.

71. The plasma reactor according to claim 63, wherein a diameter of at least one of the electrodes is greater than 10 cm.

72. The plasma reactor according to claim 63, wherein a diameter of at least one of the electrodes is less than 16 cm.

73. The plasma reactor according to claim 63, wherein a diameter of at least one of the electrodes is less than 14 cm.

74. The plasma reactor according to claim 63, wherein a diameter of at least one of the electrodes is less than 12 cm.

75. The plasma reactor according to claim 56, wherein the spacing between the electrodes is less than 2 cm.

76. The plasma reactor according to claim 56, wherein the spacing between the electrodes is less than 1.5 cm.

77. The plasma reactor according to claim 56, wherein the spacing between the electrodes is less than 1 cm.

78. The plasma reactor according to claim 56, wherein the spacing between the electrodes is greater than 0.05 cm.

79. The plasma reactor according to claim 56, wherein the spacing between the electrodes is equal to 1 cm.

80. The plasma reactor according to claim 58, wherein the gas is introduced into the plasma region through an opening in a center of the anode.

81. The plasma reactor according to claim 56, wherein a temperature of at least one of the electrodes is at least one of regulated and controlled.

82. The plasma reactor according to claim 56, wherein the frequency is inclusively between 915 MHz and 30 Ghz.

83. The plasma reactor according to claim 56, wherein the frequency is at least one of 915 MHz, 2.45 GHz and 30 GHz.

84. The plasma reactor according to claim 56, wherein a density of the power is between 5 W/cm2 and 50 W/cm2.

85. The plasma reactor according to claim 56, wherein a density of the power is 20 W/cm2.

86. The plasma reactor according to claim 56, wherein the microwaves are radiated centrally-symmetrically into the plasma region.

87. The plasma reactor according to claim 56, further comprising:
a dielectric window situated between the plasma region and the device.

88. The plasma reactor according to claim 87, wherein the dielectric window is a quartz window.

89. The plasma reactor according to claim 56, wherein the device has a waveguide which extends along the edges of the electrodes, the waveguide having at least one opening which is directed towards a center of the electrodes.

90. The plasma reactor according to claim 89, wherein the waveguide has at least two openings which are disposed adjacently in the waveguide in a direction parallel to the edges of the electrodes at a spacing of a maxima of resonator modes of the microwaves.

91. The plasma reactor according to claim 89, wherein the at least one opening is at least one slot which extends parallel to the edges of the electrodes in one plane.

92. The plasma reactor according to claim 89, wherein the at least one opening includes at least two slots which extend parallel to the edges of the electrodes in one plane, the slots being disposed at equal spacings.

93. The plasma reactor according to claim 89, wherein the at least one opening includes five slots which extend parallel to the edges of the electrodes in one plane, the slots being disposed at equal spacings.

94. The plasma reactor according to claim 89, wherein the at least one opening of the waveguide is at a spacing from the edges of the electrodes of at most 10 cm.

95. The plasma reactor according to claim 89, wherein the at least one opening of the waveguide is at a spacing from the edges of the electrodes of at most 8 cm.

96. The plasma reactor according to claim 89, wherein the at least one opening of the waveguide is at a spacing from the edges of the electrodes of at most 4 cm.

97. The plasma reactor according to claim 89, wherein the at least one opening of the waveguide is at a spacing from the edges of the electrodes of at most 3 cm.

98. The plasma reactor according to claim 89, wherein the at least one opening of the waveguide is at a spacing from the edges of the electrodes of at least 1 cm.

99. The plasma reactor according to claim 89, wherein the at least one opening of the waveguide is at a spacing from the edges of the electrodes of at least 1.5 cm.

100. The plasma reactor according to claim 89, wherein the at least one opening of the waveguide is at a spacing from the edges of the electrodes of at least 2 cm.

101. The plasma reactor according to claim 58, wherein the device is configured such that microwaves are supplied to the plasma region, viewed from the direction of the anode, behind the cathode, circulating around the edge of the cathode essentially perpendicular to a longitudinal direction thereof.

102. The plasma reactor according to claim 56, wherein the power introduced by the microwave is between 0.5 and 3 kW.

103. The plasma reactor according to claim 56, wherein the power introduced by the microwave is between 1 and 2 kW.

104. The plasma reactor according to claim 56, wherein a direct voltage is applied between the electrodes such that the power introduced by the direct voltage into the plasma is essentially as great as or less than the power introduced by the microwave.

105. The plasma reactor according to claim 56, wherein a voltage of more than 100 volts is applied between the electrodes.

106. The plasma reactor according to claim 56, wherein a voltage of more than 200 volts is applied between the electrode.

107. The plasma reactor according to claim 56, wherein a voltage of more than 300 volts is applied between the electrodes.

108. The plasma reactor according to claim 56, wherein the gas is introduced at a pressure between 10 mbar and 200 mbar.

109. The plasma reactor according to claim 56, wherein the gas is introduced at a pressure between 20 mbar and 100 mbar.

110. The plasma reactor according to claim 56, wherein the gas is introduced at a pressure between 25 mbar and 60 mbar.

111. The plasma reactor according to claim 56, wherein the gas comprises of at least one of a carbon-containing component, methane, hydrogen, argon, nitrogen, and oxygen.

112. The plasma reactor according to claim 58, further comprising:
a wafer situated on a side of the cathode orientated towards the anode.

113. The plasma reactor according to claim 58, further comprising:
a wafer situated on a side of the cathode orientated towards the anode, the wafer touching the cathode.

114. The plasma reactor according to claim 112, wherein the wafer has a layer system with a substrate layer comprising monocrystalline silicon, at least one buffer layer disposed thereon and at least one metal layer disposed thereon comprising a high-melting metal.

115. The plasma reactor according to claim 112, wherein several sequences are disposed on a substrate, comprising respectively at least one buffer layer and at least one metal layer comprising a high-melting metal.

116. The plasma reactor according to claim 115, wherein the at least one metal layer comprises of at least one of iridium, rhenium, ruthenium and platinum.

117. The plasma reactor according to claim 114, wherein the at least one buffer layer comprises of at least one of an oxidic buffer layer, silicon carbide (SiC), titanium nitride (TiN), strontium titanate (SrTiO3), barium titanate (BaTiO3), titanium oxide (TiO2), aluminium oxide (Al2O3), yttrium-stabilised zirconium oxide (YSZ), Y2O3, MgO and cerium oxide (CeO2).

118. The plasma reactor according to claim 114, wherein the at least one buffer layer has a thickness between 1 and 2,000 nm.

119. The plasma reactor according to claim 114, wherein the at least one buffer layer has a thickness between 1 and 100 nm.

120. The plasma reactor according to claim 114, wherein the at least one buffer layer has a thickness between 10 and 50 nm.

121. The plasma reactor according to claim 114, wherein the at least one metal layer has a thickness between 10 and 1,000 nm.

122. The plasma reactor according to claim 114, wherein the at least one metal layer has a thickness between 50 and 200 nm.

123. The plasma reactor according to claim 114, wherein the buffer layer has a faulty orientation >2° with respect to at least one of tilt and twist.

124. The plasma reactor according to claim 114, wherein the buffer layer has a faulty orientation >1° with respect to at least one of tilt and twist.

125. The plasma reactor according to claim 114, wherein the buffer layer has a faulty orientation >0.5° with respect to at least one of tilt and twist.

126. The plasma reactor according to claim 112, wherein the wafer has an Ir/metal oxide/silicon layer system, the metal oxide comprising of one of SrTiO3 and yttrium-stabilised zirconium oxide (YSZ), the crystallographic surfaces of at least one layer of the layer system being (001) and (111).

127. The plasma reactor according to claim 112, wherein the wafer has an Ir/metal oxide/silicon layer system, the metal oxide comprising of one of SrTiO3 and yttrium-stabilised zirconium oxide (YSZ), the crystallographic surfaces of the Ir layer being (001) and (111).

128. The plasma reactor according to claim 112, wherein the wafer has at least one metal layer which has an essentially monocrystalline orientation.

129. The plasma reactor according to claim 112, wherein the wafer has at least one metal layer which has an essentially monocrystalline orientation, the at least one of metal layer at least one of having a mosaicity <3° and being fibre-textured.

130. The plasma reactor according to claim 112, wherein the wafer has at least one metal layer which has an essentially monocrystalline orientation, the at least one of metal layer at least one of having a mosaicity <2° and being fibre-textured.

131. The plasma reactor according to claim 112, wherein the wafer has at least one metal layer which has an essentially monocrystalline orientation, the at least one of metal layer at least one of having a mosaicity <1° and being fibre-textured.

132. The plasma reactor according to claim 56, wherein an area of at least one of (a) at least one of the electrodes and (b) the wafer is greater than 600 mm2.

133. The plasma reactor according to claim 56, wherein an area of at least one of (a) at least one of the electrodes and (b) the wafer is greater than 2,000 mm2.

134. The plasma reactor according to claim 56, wherein an area of at least one of (a) at least one of the electrodes and (b) the wafer is greater than 4,000 mm2.

135. The plasma reactor according to claim 56, wherein an area of at least one of (a) at least one of the electrodes and (b) the wafer is greater than 7,000 mm2.

136. The plasma reactor according to claim 56, wherein an area of at least one of (a) at least one of the electrodes and (b) the wafer is greater than 7,800 mm2.

137. The plasma reactor according to claim 56, wherein an area of at least one of (a) at least one of the electrodes and (b) the wafer is greater than 11,000 mm2.

138. The plasma reactor according to claim 58, wherein a first area of the anode is substantially equal to or exactly equal to a second area of the cathode.

139. The plasma reactor according to claim 58, further comprising:
a metal cylinder being one of hollow and solid, the metal cylinder being disposed on a side of the cathode orientated away from the anode, a circumference of the metal cylinder extending essentially parallel to the edge of the cathode.

140. The plasma reactor according to claim 58, further comprising:
a metal cylinder being one of hollow and solid, the metal cylinder being disposed on a side of the anode orientated away from the cathode, a circumference of the metal cylinder extending essentially parallel to the edge of the anode.

141. The plasma reactor according to claim 56, wherein surfaces of the electrodes are flat.

142. The plasma reactor according to claim 58, wherein a surface of the cathode is flat, a surface of the anode deviating from a flat shape such that the surface of the anode is closer to the cathode towards the edge.

143. The plasma reactor according to claim 58, wherein a surface of the cathode is flat, a surface of the anode deviates from a flat form such that the surface of the anode is closer to the cathode towards the center.

144. The plasma reactor according to claim 56, further comprising:
a microwave generator producing the microwaves.

145. A method for nucleation of diamond on at least one wafer, comprising:
situating the wafer between a flat anode and a flat cathode;
introducing a plasma in a region between the wafer and the anode, an ion saturation current density of the plasma being greater than or equal to 0.001 A/cm2,
introducing at least one gas containing a carbon source into the region;
applying a direct voltage between the anode and the cathode such that an electrical field consequently produced between the anode and the cathode permeates the gas present in the region; and
radiating microwaves into the gas present in the region.

146. The method according to claim 144, wherein the ion saturation current density of the plasma is greater than or equal to 0.0015 A/cm2.

147. The method according to claim 144, wherein the ion saturation current density of the plasma is greater than or equal to 0.002 A/cm2

148. The method according to claim 144, wherein the ion saturation current density of the plasma is greater than or equal to 0.003 A/cm2.

149. The method according to claim 145, wherein the wafer is disposed on the cathode, the wafer touching the cathode.

150. The method according to claim 148, wherein the applied direct voltage is greater than 100 volts.

151. The method according to claim 148, wherein the applied direct voltage is greater than 200 volts.

152. The method according to claim 148, wherein the applied direct voltage is greater than 300 volts.

153. The method according to claim 148, wherein the gas comprises of at least one of methane, hydrogen, argon, nitrogen and oxygen.

154. The method according to claim 144, wherein a power introduced into the gas via the microwaves is between 0.5 kW and 3 kW.

155. The method according to claim 144, wherein a power introduced into the gas via the microwaves is between 1 kW and 2 kW.

156. The method according to claim 144, wherein the power density introduced into the gas by at least one of (a) the microwave and (b) the direct voltage respectively is between 10 and 25 W/cm2.

157. A method for coating with diamond, comprising:
depositing nucleation nuclei deposited on a wafer by situating the wafer between a flat anode and a flat cathode;
introducing a plasma in a region between the wafer and the anode, an ion saturation current density of the plasma being greater than or equal to 0.001 A/cm2,
introducing at least one gas containing a carbon source into the region;
applying a direct voltage between the anode and the cathode such that an electrical field consequently produced between the anode and the cathode permeates the gas present in the region; and
radiating microwaves into the gas present in the region and growing a diamond layer on the wafer.
